(19) United States
(12) Patent Application Publication
(10) Pub. No.: US 2026/0057124 A1
(43) Pub. Date: Feb. 26, 2026

(54) GUIDED LIGHTING DESIGN

(71) Applicant: SIGNIFY HOLDING B.V., EINDHOVEN (NL)

(72) Inventors: NAM CHIN CHO, PEACHTREE CITY, GA (US); ROBERT BABIARZ, MISSISSAUGA (CA); SANDYA BALAKRISHNAN, ATLANTA, GA (US); KAITLIN BURKE, ATLANTA, GA (US); CAROL CARR-ADAMS, ATLANTA, GA (US); TRAVIS JOHNSON, FAYETTEVILLE, TN (US)

(21) Appl. No.: 19/299,696

(22) Filed: Aug. 14, 2025

Related U.S. Application Data
(60) Provisional application No. 63/686,872, filed on Aug. 26, 2024.

(30) Foreign Application Priority Data
Sep. 10, 2024 (EP) 24199478.9

(51) Int. Cl. G06F 30/13

(52) U.S. Cl. CPC G06F 30/13

(57) ABSTRACT

A lighting design method includes receiving a map of a geographic area and displaying the map of the geographic area on a screen. The method includes displaying a boundary line overlaid on the map in response to a boundary line user input provided to the user device, where a lighting design target area is bound by the boundary line. The method includes displaying a light fixture model overlaid on the map within the lighting design target area, where the light fixture model is overlaid at a location indicated by a location indicator user input and where the light fixture model represents a light fixture selected from a light fixture menu. The method further includes generating illuminance information at least based on user provided information including a configuration of the light fixture and displaying, by the user device, the illuminance information overlaid on the lighting design target area.

### FIELD OF THE INVENTION

The present disclosure relates generally to lighting designs, and more particularly to guided lighting design based on maps of areas.

### BACKGROUND OF THE INVENTION

Performing a lighting design for an area typically involves a person traveling to the area and examining the area in person. For example, the person may measure the size of the area, determine the presence and location of structures such as buildings, etc. and use a lighting modeling software to estimate lighting for the area based on the measured dimensions, locations of structures, etc. Typically, a model of the area is first created using information gathered during physical presence in the area, and the created model is then used to perform lighting design for the area. The lighting design for the area is heavily dependent on the accuracy of the information (e.g., size, sections of the area that need different lighting, etc.) and on the models of the area created from the collected information. Changes to the size and/or sections of the area intended for lighting design may require generating new models that can be a cumbersome task. In addition, lighting design software tools are typically complex and require extensive lighting design knowledge to perform lighting design using such tools. Thus, a lighting design method that avoids the need for a lighting designer to physically visit a light design target area and that simplifies the lighting design process may be desirable.

### SUMMARY OF THE INVENTION

The present disclosure relates generally to lighting solutions, and in particular to guided lighting design based on maps of areas. In an example embodiment, a lighting design method includes receiving a map of a geographic area and displaying the map of the geographic area on a screen. The method further includes displaying a boundary line overlaid on the map in response to a boundary line user input provided to the user device, where a lighting design target area is bound by the boundary line. The method also includes displaying a light fixture model overlaid on the map within the lighting design target area, where the light fixture model is overlaid at a location indicated by a location indicator user input and where the light fixture model represents a light fixture selected from a light fixture menu displayed on the screen. The method further includes generating illuminance information at least based on user provided information including a configuration of the light fixture and displaying, by the user device, the illuminance information overlaid on the lighting design target area.

These and other aspects, objects, features, and embodiments will be apparent from the following description and the appended claims.

### BRIEF DESCRIPTION OF THE FIGURES

Reference will now be made to the accompanying drawings, which are not necessarily drawn to scale, and wherein:

FIG. 1 illustrates a lighting design system for performing lighting design based on a map of an area according to an example embodiment;

FIG. 2A illustrates a first part of a method of performing a lighting design using the user device of FIG. 1 according to an example embodiment;

FIG. 2B illustrates a second part of the method of FIG. 2A;

FIG. 3 illustrates a map displayed on a screen of the user device according to an example embodiment;

FIG. 4 illustrates the boundary line overlaid on the map and a light fixture menu user input displayed on the screen of the user device according to an example embodiment;

FIG. 5 illustrates a light fixture menu displayed on the screen of the user device according to an example embodiment;

FIG. 6 shows the light fixture selected from the light fixture menu of FIG. 5 displayed on the screen of the user device according to an example embodiment;

FIG. 7 illustrates a light fixture model representing the selected light fixture overlaid on the map within the lighting design target area bound by the boundary line according to an example embodiment;

FIG. 8 illustrates multiple light fixture models overlaid on the map in the lighting design target area bound by the boundary line according to an example embodiment;

FIG. 9 illustrates user input entry features displayed on the screen of the user device for providing lighting characteristics user inputs to the user device according to an example embodiment;

FIG. 10 illustrates illuminance information overlaid on the map in the lighting design target area according to an example embodiment;

FIG. 11 illustrates a lighting design summary displayed on the screen of the user device according to an example embodiment; and

FIG. 12 shows a lighting design list that is displayed on the screen of the user device according to an example embodiment.

The drawings illustrate only example embodiments and are therefore not to be considered limiting in scope. The elements and features shown in the drawings are not necessarily to scale, emphasis instead being placed upon clearly illustrating the principles of the example embodiments. Additionally, certain dimensions or placements may be exaggerated to help visually convey such principles. In the figures, the same reference numerals used in different figures may designate like or corresponding and not necessarily identical elements.

### DETAILED DESCRIPTION OF THE EXAMPLE EMBODIMENTS

In the following paragraphs, example embodiments will be described in further detail with reference to the figures. In the description, well-known components, methods, and/or processing techniques are omitted or briefly described. Furthermore, reference to various feature(s) of the embodiments is not to suggest that all embodiments must include the referenced feature(s).

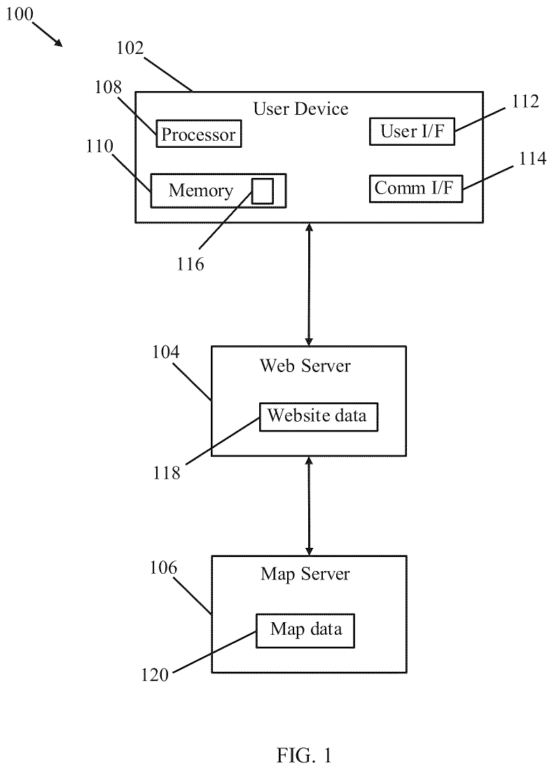

FIG. 1 illustrates a lighting design system 100 for performing lighting design based on a map of an area according to an example embodiment. For example, the map of an area may be a satellite view of the area. In some example embodiments, the system 100 may include a user device 102, a web server 104, and a map server 106. The user device 102 may communicate with the web server 104 via wired and/or wireless connections. For example, the user device 102 may execute an application, such as an internet browser application or another application, to access a lighting design website 118 hosted on the web server 104. A user (e.g., a consumer) may enter the internet address of the lighting design website 118 into an internet browser application (i.e., an internet browser) of the user device 102 to access the lighting design website 118. For example, a user may enter a uniform resource locator (URL) of the lighting design website 118. The internet browser application may be MICROSOFT EDGE, CHROME, FIREFOX, or another application. In some alternative embodiments, opening an application resident in the user device 102 may access the website 118 by default.

In some example embodiments, the web server 104 may host the lighting design website 118 that can be used for lighting design based on a map of an area, where the map is accessible from the map server 106. For example, the map server 106 may include map data 120 of different areas and may provide a map of a particular area based on a request from the web server 104. The web server 104 may access maps of different areas from the map server 106 via an application programming interface (API). The map server 106 may provide a mapping service the delivers maps of areas as map view images, satellite view images, street view images, and/or other types of images. For example, the map server 106 may be a GOOGLE Maps server. In some example embodiments, the user device 102 may be used to perform a lighting design based on user inputs. To illustrate, the user device 102 may include a processor 108, a memory device 110, a user interface 112, and a communication interface 114. The processor 108 may include, for example, a microprocessor). The memory device 110 may include a static memory device (e.g., a flash memory). A software code 116 and other information may be stored in the memory device 110. For example, the software code 116 may include executable code that can be executed by the processor 108 to perform operations described herein with respect to the user device 102. Data that is used and/or generated by the processor 108 may also be stored in the memory device 110.

In some example embodiments, the user interface 112 may include one or more of a keyboard, a keypad, a mouse, a touch-sensitive screen, a display screen, etc. for receiving user inputs and/or for displaying information. For example, the user device 102 may be a desktop, a portable device (e.g., a laptop, a tablet, a mobile phone), or another type of device. The user device 102 may communicate with the web server 104 and other devices via the communication interface 114. For example, the communication interface 114 may include wired and/or wireless communication components such as one or more transmitters and one or more receivers that operate based on one or more communication standards as can be readily understood by those of ordinary skill in the art with the benefit of this disclosure.

In some example embodiments, the user device 102 may perform a lighting design for a lighting design target area identified or otherwise indicated by a user. For example, after an internet browser is opened in the and a webpage of the lighting design website 118 is displayed on a screen of the user device 102, the user may provide a geographic location user input to the user device 102, for example, as an input to the webpage of the lighting design website 118. The user may provide location information, such as street address, street names, city, state, area name, building name, and/or other information, to the displayed webpage of the lighting design website 118. For example, the lighting design website 118 hosted by the web server 104 may include a user input space in the web page displayed on the user device 102 for entering (e.g., typing) the location information. The web server 104 may retrieve from the map server 106 a map showing a geographic area including the location indicated by the geographic location user input. The user device 102 may then display the map in a webpage of the lighting design website 118 displayed by the internet browser at the user device 102. For example, the map may be a satellite view of a geographic area that includes the location indicated by the location information provided as the geographic location user input.

In some example embodiments, after a map retrieved from the map server 106 is displayed on the user device 102, a user may manipulate the map displayed on the user device 102. To illustrate, a user may change views, zoom in, zoom out, move, and/or perform other operations with the map. For example, a user may be able to manipulate a map displayed on the user device 102 in a manner that can be performed on a map displayed in an internet browser by Google Maps.

In some example embodiments, after a map is displayed on the user device 102 as described above, a user may provide a user input to the user device 102 to identify or otherwise indicate a specific lighting design target area within the geographic area shown in the displayed map. For example, a user may provide a boundary line user input to the user device 102 via the user interface 112. For example, a user may draw a boundary line overlaid on the displayed map, where the boundary line encloses the intended lighting design target area. To illustrate, a user may use a mouse or a finger on touch-sensitive screen of the user device 102 to draw the boundary line on the displayed map, where the boundary line encloses or otherwise bounds the intended lighting design target area. For example, the lighting design target area may include a parking lot, a walkway, a driveway, a sidewalk, and/or another outdoor area.

In some example embodiments, a webpage of the lighting design website 118 displayed on the screen of the user device 102 may include user input entry features such as a menu (e.g., selectable tiles or a drop down menu), a selectable icon, a text entry form field, menu, etc. for a user to provide user inputs to the user device 102. For example, the user input entry features may be displayed in addition to a map of a geographic area and a boundary line drawn by the user as described above. To illustrate, a user may click on or otherwise select a menu icon shown on the webpage to display a menu of light fixtures, categories of light fixtures, etc. For example, the menu may include options to refine the selection of light fixtures in steps to select a particular light fixture or type of light fixture. A user may provide an input to the user device 102, for example, using a mouse or a finger, to select a particular light fixture (or type of light fixture) from the displayed menu. The user may also provide an input to the user device 102 to a place a light fixture model of the selected light fixture in the lighting device target area shown in the map. For example, the user may click at or otherwise indicate a particular location in the lighting design target area to indicate the desired location of the light fixture model. Additional light fixture models may be placed in the lighting design target area by clicking or otherwise indicating desired locations of the light fixture models.

In some example embodiments, the user device 102 may receive additional user inputs using the user input entry features displayed in the webpage. For example, a user may provide an input indicating a desired mounting height of the light fixtures represented by the light fixture models displayed in the lighting design target area. In some cases, a single mounting height may be associated with all light fixtures represented by the light fixture models displayed in the lighting design target area. After the light fixture models are placed in the lighting design target area, each light fixture model may be selected by a user, for example, by clicking on the particular light fixture model, and the user may provide a configuration user input to the user device 102. For example, the configuration user input may include the number of heads of the light fixture represented by the selected light fixture model, the orientation of the head(s), a vertical tilt angle, etc. The user may provide a configuration user input with respect to each one of the light fixture models for individually selecting the light fixture models.

In some example embodiments, a user may provide a lighting characteristics user input to the user device 102 via a user input feature of the webpage displayed on the screen (i.e., the user interface 112) of the user device 102. For example, after the user provides configuration user inputs to indicating the desired configuration of the light fixtures represented by the displayed light fixture models, a user may provide to the user device 102 lighting characteristics user input that indicate desired lighting characteristics for the lighting design target area such as correlated color temperature (CCT), minimum light level, and/or lighting uniformity. The user may provide the lighting characteristics user input to the user device 102 using user input entry features (e.g., drop down menu or text entry form field) that appear in the displayed webpage.

In some example embodiments, the user device 102 may process the user provided information to generate illuminance information for the lighting design target area enclosed by the boundary line drawn or otherwise defined by the user. Illuminance information generated by the user device 102 may include illuminance values for different locations in the lighting design target area. For example, in response to a user input, the user device 102 may process user provided information, including the mounting height of the light fixtures and the configuration of individual light fixtures, to generate illuminance information. To illustrate, with respect to each light fixture in the lighting design target area, the user device 102 may select a photometric data file from among multiple photometric data files based on user provided information such as mounting height and individual light fixture configuration, for example, through an iterative process such that the lighting in the lighting design target area has the desired lighting characteristics indicated by the user.

In some example embodiments, using IES files as representing photometric data files, the user device 102 or another component of the lighting design system 100 may execute an intelligent IES file selection algorithm that can utilize linear optimization techniques and/or artificial intelligence (AI)-driven models to select IES files with respect to each light fixture model and thus each light fixture represented by each light fixture. The user device 102 may execute the algorithm using user provided information including the dimensions of the lighting design target area defined by the boundary line, desired illumination level and uniformity targets, and fixture specifications (e.g., configuration information). The user device 102 may execute the algorithm to perform an optimization task aiming to minimize the discrepancy between desired illumination as indicated by the user and actual illumination as determined based on IES files, where constraints ensure compatibility with the boundary and fixture positions. The algorithm may assign weights to different IES files based on their suitability. An AI model is also trained on historical data, predicting the optimal IES file(s) for each fixture and scenario. Such a hybrid approach can dynamically adjust weights assigned to the IES files based on real-time feedback.

In general, a diverse dataset of IES files, lighting layouts (e.g., number of light fixtures, locations of light fixtures, shape of lighting design target area, and/or other layout factors), and lighting scenarios can be curated and used to train an IES file selection AI model. User feedback and performance metrics can also guide continuous improvement of the IES file selection. As users refine their lighting designs, the algorithm can reevaluate IES file choices and adapt to changes.

After identifying or selecting a photometric data file (e.g., IES file) with respect to each light fixture represented by a light fixture model in the lighting design target area, the user device 102 may generate and display the illuminance information that is overlaid on the map in the lighting design target area. As indicated above, the illuminance information may include illuminance values calculated for different locations in the lighting design target area. Alternatively or in addition, the illuminance information may include a heatmap that shows different colors and/or patterns representing different illuminance values at different locations in the lighting design target area. The photometric data files may be stored in the user device 102, at the web server 104, or at another server and may be accessible by the user device 102 to generate the illuminance information. In general, the user device 102 may not require a user to manually select or otherwise indicate photometric data files with respect to the light fixtures represented by the displayed light fixture models.

In some example embodiments, a user may move, add, and/or delete a light fixture model displayed in the lighting design target area shown in the map displayed by the user device 102. For example, a user may change the number and/or locations of light fixture models in the displayed lighting design target area before or after the user device 102 generates the illuminance information. To illustrate, after the user device 102 generates the illuminance information and displays the illuminance information overlaid on the map in the lighting design area, the user may review the displayed the illuminance information and decide to change the number and/or locations of light fixture models, the mounting height, the configuration of the light fixtures represented by the light fixture models, etc. After the changes by the user, the user device 102 may parse through the user provided information (i.e., newly and previously provided) and generate new illuminance information, for example, based on photometric data from newly and/or previously identified/selected photometric data files.

In some example embodiments, the user device 102 may generate and display a lighting design summary in response to a user input requesting the summary. The lighting design summary may include identifiers (e.g., names) of light fixtures represented by the displayed light fixture models, mounting height, configuration information of the light fixtures, photometric data file identifiers, etc.

In some example embodiments, after the illuminance information is displayed overlaid on the map, the user device 102 may store lighting design information that can be subsequently accessed to redisplay the image. For example, the user device 102 may access the stored lighting design information to display the map, the boundary line overlaid on the map, the light fixture models overlaid on the map within the lighting design target area, and the illuminance information overlaid on the map.

In some example embodiments, the user device 102 may use another component of the lighting device system 100 to perform some operations described herein. For example, the user device 102 may use the web server 104 or another server to process the user provided information, to select photometric data files, and/or to generate the illuminance information.

In some alternative embodiments, the system 100 may include additional or different components than shown without departing from the scope of this disclosure. In some alternative embodiments, the system 100 may have a different configuration of components than shown without departing from the scope of this disclosure.

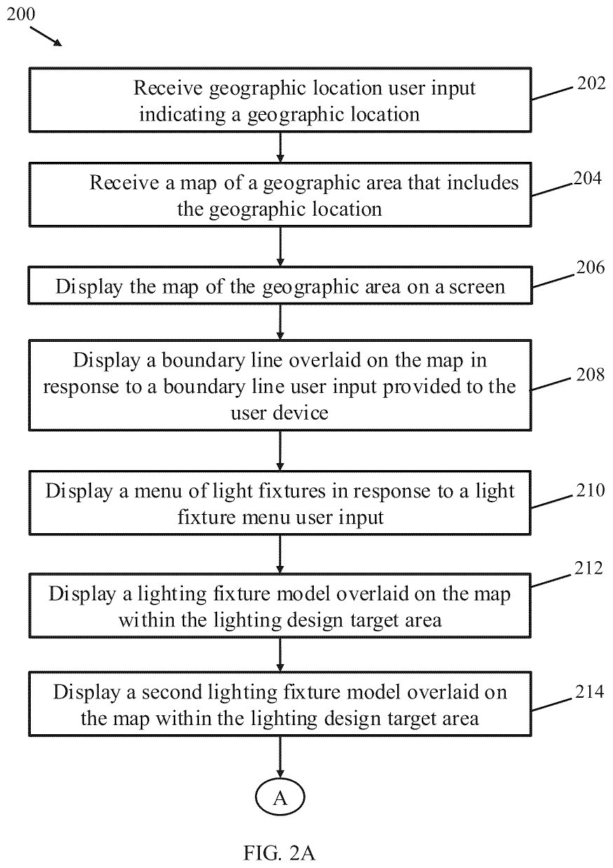

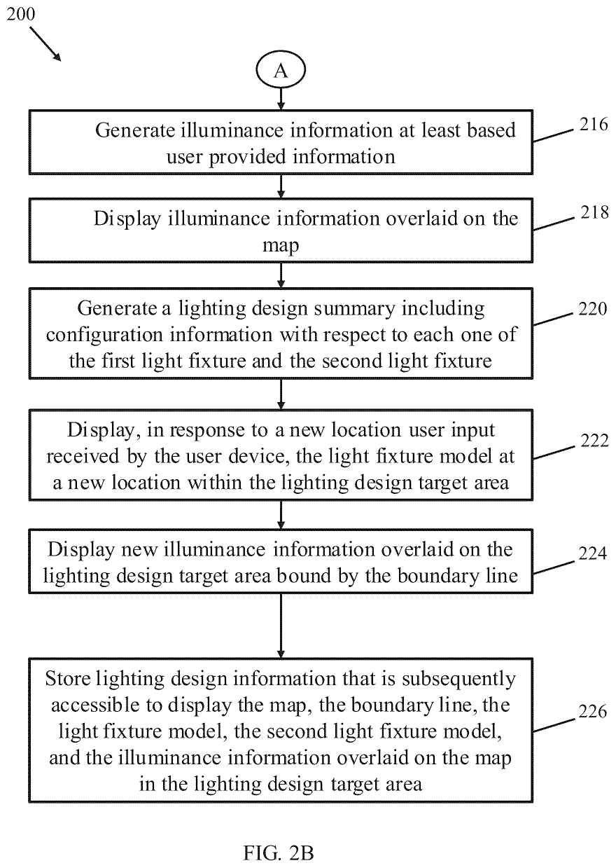

FIGS. 2A and 2B illustrate a method 200 of performing a lighting design using the user device of FIG. 1 according to an example embodiment. Referring to FIGS. 1, 2A, and 2B, in some example embodiments, the method 200 includes, at step 202, receiving, by the user device 102, a geographic location user input indicating a geographic location. For example, the geographic location may be a street address, a street name, a city, a state, an area name, a building name, and/or another location identifier information. In general, the user device 102 may execute an internet browser-based application to perform the lighting design. For example, a user may access the lighting design website 118 using an internet browser or an internet browser-based application executed by the use device 102. A person may type in a geographic location in a text entry form field of, for example, a webpage displayed on a screen of the user interface 112 of the user device 102.

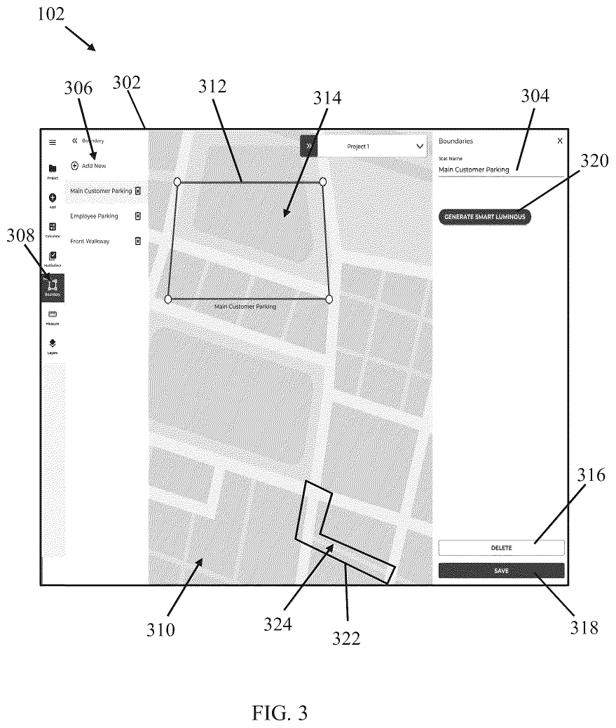

In some example embodiments, at step 204, the method 200 may include receiving, by the user device 102, a map of a geographic area that includes the geographic location. For example, the map server 106 may provide the map to the user device 102 via the web server 104 in response to location information sent by the user device 102 indicating the geographic location. In general, the map may include the geographic location indicated by the geographic location user input as well as the surrounding areas. At step 206, the method 200 may include displaying, by the user device 102, the map of the geographic area on a screen. For example, FIG. 3 illustrates a map 310 displayed on a screen 302 of the user device 102 according to an example embodiment. To illustrate, the user interface 112 of the user device 102 may include the screen 302 (e.g., a smartphone screen, a tablet screen, or a laptop monitor) according to an example embodiment. The map 310 may be a satellite view or a map view of a geographic area that includes the location indicated by the location information provided as the geographic location user input at step 202. In general, the map 310 may show the locations and representations of structures such as buildings, roads, walkways, etc.

Referring to FIGS. 1-3, in some example embodiments, at step 208, the method 200 includes displaying a boundary line 312 overlaid on the map 310 in response to a boundary line user input provided to the user device 102. For example, a user may click on, using a mouse, or touch with a finger an icon 308 displayed on the screen 302 to initiate providing the boundary line user input to the user device 102. For example, after clicking on the icon 308, the user may draw or otherwise indicate the boundary line 312 on the map 310, where the boundary line 312 encloses a lighting device target area 314. That is, the user's objective is to perform a lighting design for the lighting device target area 314. The user can provide an input to the user device 102 labelling the boundary line 312, for example, using a text entry form field 304 displayed on the screen 302. In general, the user may provide one or more inputs to the user device 102 to zoom in, zoom out, move, etc. with respect to the map 310 before the boundary line 312 is displayed.

In some example embodiments, after the boundary line 312 is displayed on the screen 302, the user may provide an input to the user device 102, for example, by clicking on an icon 318 displayed on the screen 302, to save information that enables displaying the boundary line 312, for example, as shown in FIG. 3, upon retrieval at a later time. To illustrate, the user may select from a list 306 of saved boundary lines instead of or in addition to drawing a new boundary line.

In some example embodiments, the user may add another boundary line 322 enclosing another lighting design target area 324. In general, the user may provide an input to the user device 102 to draw a boundary line that forms different shapes enclosing an area of the map 310. The user may also provide an input to the user device 102 to remove a particular boundary line from the map 310. For example, after selecting the boundary line 322, the user may click on or touch an icon 316 to delete the boundary line 322 from the screen 302. After the desired lighting target area/areas (e.g., the target area 314) on the map 310 is/are identified by the boundary line(s) overlaid on the map 310, the user can continue with the rest of the lighting design process. For example, the user may continue with the lighting design for the lighting design target area 314 by clicking on an icon 320 after the boundary line 322 is deleted.

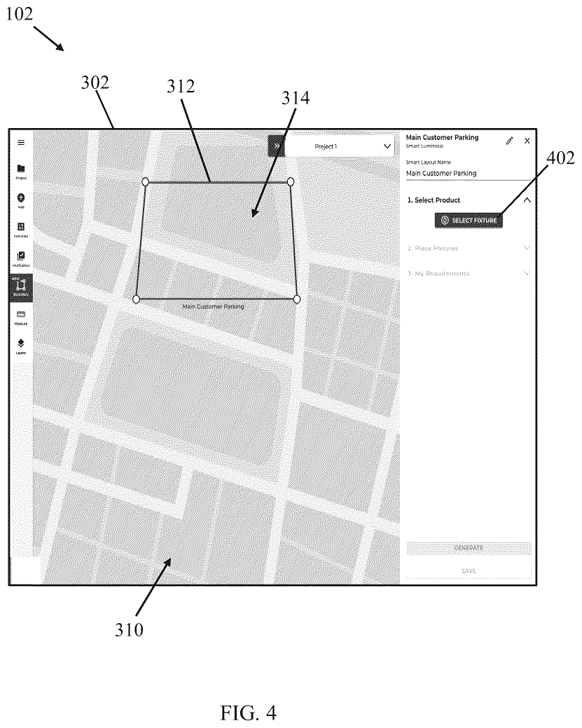

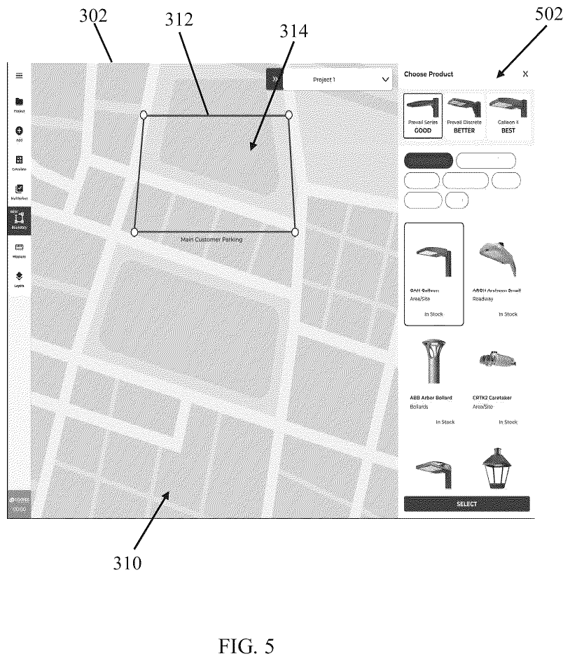

In some example embodiments, at step 210, the method 200 includes displaying a menu of light fixtures in response to a light fixture menu user input. For example, FIG. 4 illustrates the boundary line 312 overlaid on the map 310 and a light fixture menu user input 402 displayed on the screen of the user device 102 according to an example embodiment, and FIG. 5 illustrates a light fixture menu displayed on the screen of the user device 102 according to an example embodiment. Referring to FIGS. 1-5, in some example embodiments, in response to the user clicking or touching the icon 320 shown in FIG. 3, the user device 102 may display light fixture menu user input 402 shown in FIG. 4. In response to the user clicking or touching the light fixture menu user input 402, the user device 102 may display a light fixture menu 502 on the screen 302.

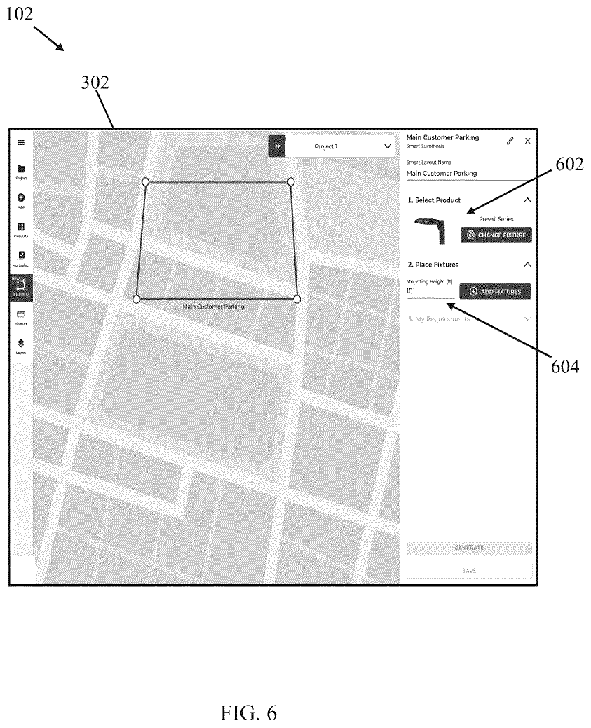

In some example embodiments, the light fixture menu 502 may be displayed along with the map 310 and the boundary line 312 overlaid on the map 310 around the lighting design target area 314. The light fixture menu 502 may include different options to refine the selection of a light fixture or a family of light fixtures. The user may select a particular light fixture from the light fixture menu 502. To illustrate, FIG. 6 shows the light fixture selected from the light fixture menu 502 of FIG. 5 displayed on the screen 302 of the user device 102 according to an example embodiment. Referring to FIGS. 1-6, in some example embodiments, the user device 102 may provide the user with an option to change the selected light fixture or to add another light fixture. For example, the user device 102 may receive a user input via a user input entry feature 602 displayed on the screen 302 as shown in FIG. 6 to change the light fixture selected using the light fixture menu 502 shown in FIG. 5. The user device 102 may display the light fixture menu 502 shown in FIG. 5 in response to a user providing a user input, for example, by clicking or touching the user input entry feature 602. The user may also provide a height information to the user device 102 to indicate the mounting height of the selected light fixture, for example, by entering the height value at a text entry form field 604 displayed on the screen 302.

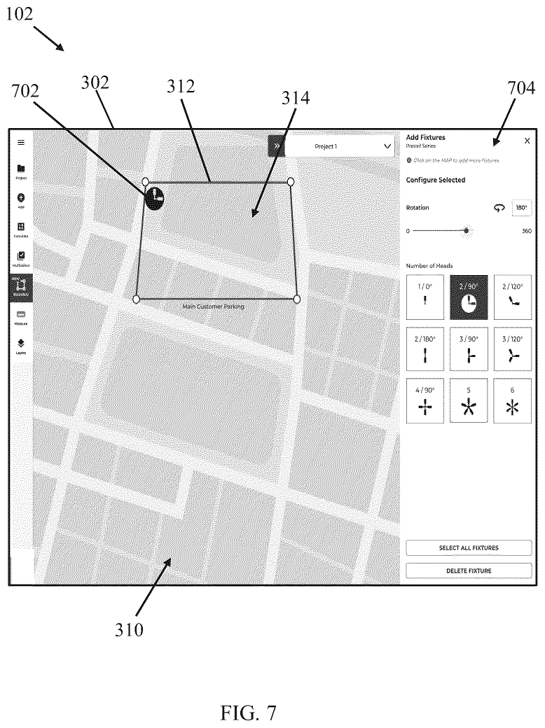

In some example embodiments, at step 212, the method 200 includes displaying a light fixture model overlaid on the map 310 within the lighting design target area 314. For example, FIG. 7 illustrates a light fixture model 702 representing the selected light fixture overlaid on the map 310 within the lighting design target area 314 bound by the boundary line 312 according to an example embodiment. For example, the light fixture model 702 may be placed at the particular location in the lighting design target area 314 in response to a location indicator user input provided to the user device 102 by the user. To illustrate, in response to the user clicking at or touching a particular location in the lighting design target area 314, the user device 102 may place the light fixture model 702 overlaid on the map 310 at the indicated location. The user device 102 may display a configuration menu 704 on the screen 302, and the user may provide configuration user inputs to configure the light fixture represented by the light fixture model 702. For example, the user device 102 may display a configuration menu 704 in response to the selection of the light fixture model 702, for example, by clicking or touching the light fixture model 702. The configuration user inputs that can be provided to the user device using the configuration menu 704 may indicate number of heads, rotation angle, tilt angle, etc. as can be readily understood by those of ordinary skill in the art with the benefit of this disclosure.

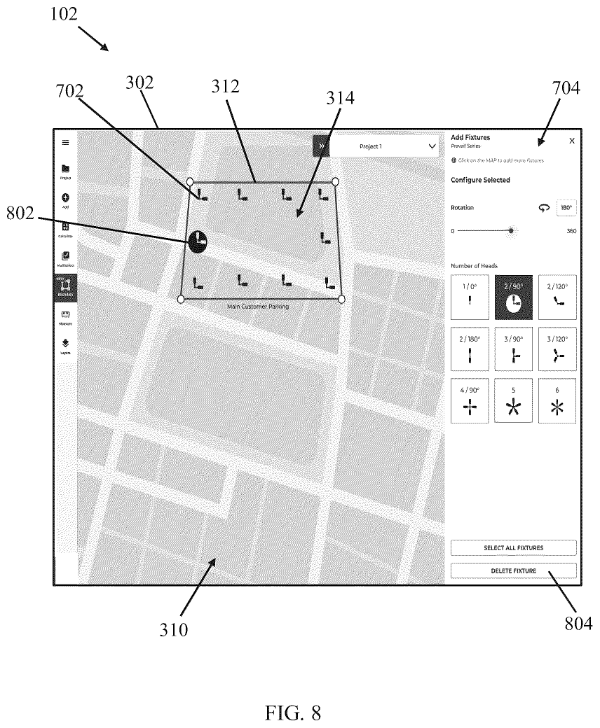

In some example embodiments, at step 214, the method 200 may include displaying another light fixture model overlaid on the map 310 within the lighting design target area 314. To illustrate, after the light fixture model 702 is placed in the lighting design target area 314, the user may indicate one or more other locations in the lighting design target area 314 for placing one or more additional light fixture models. In response to the user clicking or touching a location in the lighting design target area 314, the user device 102 may place another light fixture model. For example, FIG. 8 illustrates multiple light fixture models overlaid on the map 310 in the lighting design target area 314 bound by the boundary line 312 according to an example embodiment. To illustrate, after the light fixture model 702 is displayed overlaid on the map 310 as described with respect to FIG. 7, the user may provide to the user device 102 an input (e.g., clicking with a mouse or touching the screen 302 with a finger) indicating a location in the lighting design target area 314 for placing another light fixture model such as a light fixture model 802. Other light fixture models can be added in the lighting design target area 314 in the same manner by the user indicating respective locations.

After one or more of the light fixture models including the light fixture models 702, 802 are placed in the lighting design target area 314, the light fixtures represented by the light fixture models may be individually or collectively configured in response to configuration user inputs in the manner described above with respect to the light fixture model 702. For example, after selecting the light fixture model 802, the user may use the configuration menu 704 to configure the light fixture represented by the light fixture model 802. For example, number of heads, tilt angle, rotation angle (pan angle), etc. may be configured using the configuration menu 704. To be clear, a default configuration may be associated with each light fixture represented by the light fixture models placed in the lighting design target area 314.

In some example embodiments, the user device 102 may delete a light fixture model in response to a user input (i.e., a light fixture removal user input) provided by the user. For example, a user may select a particular light fixture model displayed on the screen 302 and click or touch a removal icon 804 displayed on the screen 302 to remove the particular selected light fixture model. The user may also provide a user input to the user device 102 to change the location of a light fixture model within the lighting design target area 314.

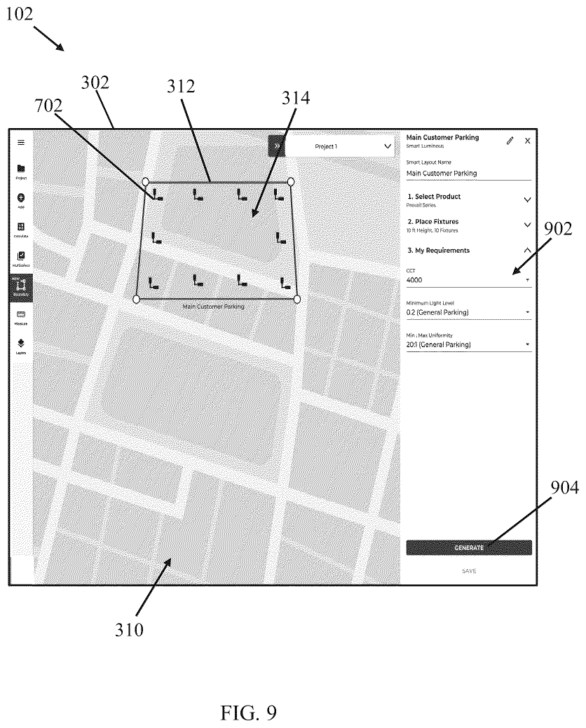

In some example embodiments, after the light fixtures represented by the light fixture models including the light fixture models 702, 802 are configured as described above, the user may provide to the user device 102 lighting characteristics user inputs indicating desired lighting characteristics of the lighting design target area 314. For example, FIG. 9 illustrates user input entry features 902 displayed on the screen 302 of the user device 102 for providing lighting characteristics user inputs to the user device according to an example embodiment. To illustrate, the user input entry features 902 may include drop down menus, text entry form fields, or other input entry options for providing parameter values such as desired CCT (e.g., 2700 K, 3000 K, 3500 K, 4000 K, 5000 K, 6000 K, etc.), desired minimum light level (e.g., 0.1, 0.2, etc.), desired min/max uniformity ratio (e.g., 20:1, 15:1, 5:1, etc.), etc. with respect to the lighting design target area 314. For example, a user may select from among multiple values displayed on the screen 302, for example, as a drop down menu with respect to each one of CCT, minimum light level, and min/max uniformity ratio. A default value may be assigned to each one of CCT, minimum light level, and min/max uniformity ratio. may enter (e.g., type in) desired values.

In some example embodiments, at step 216, the method 200 of FIGS. 2A and 2B may include generating illuminance information at least based user provided information. Referring to FIGS. 1-9, in some example embodiments, the user device 102 may process the user provided information and generate (e.g., calculate) illuminance values at different locations in the lighting design target area 314 in response to a user input. For example, the user may click or touch a generate icon 904 displayed on the screen 302 (shown in FIG. 9) as an input to the user device 102 to generate illuminance information for the lighting design target area 314. In response to the user input provided using the generate icon 904, the user device 102 may determine/calculate illuminance values for different locations in the lighting design target area 314 using photometric data from photometric data files (e.g., IES files) as readily understood by person of ordinary skill in the art. The boundary line 312 serves to define the boundary of the lighting design target area 314 as the area of interest for calculating the illuminance values and for displaying the illuminance information.

For example, with respect to each displayed light fixture model (e.g., the light fixture models 702, 802, etc.) and the corresponding light fixture represented by the light fixture model, the user device 102 may select a photometric data file (e.g., IES file) from among multiple photometric data files based on the mounting height of the light fixture and the configuration of the light fixture such that the lighting design target area 314 has the desired lighting characteristics (e.g., CCT, min light level, min/max uniformity) indicated by the user as can be readily understood by those of ordinary skill in the art with the benefit of this disclosure. Along with photometric data files, the user device 102 may select an optics from among available optics with respect to each light fixture based on the user provided information such that the lighting design target area 314 has the desired lighting characteristics (e.g., CCT, min light level, min/max uniformity) indicated by the user as can be readily understood by those of ordinary skill in the art with the benefit of this disclosure.

With respect to different locations on the ground in the lighting design target area 314 and with respect to each displayed light fixture model (e.g., the light fixture models 702, 802, etc.) and the corresponding light fixture represented by the light fixture model, the user device 102 calculate, illuminance values based on photometric data from a photometric data file, the mounting height of the light fixture, and/or the configuration of the light fixture as can be readily understood by those of ordinary skill in the art with the benefit of this disclosure. The user device 102 may generate the illuminance information for the lighting design target area 314 based on the illuminance values determined with respect to individual light fixtures. The illuminance information may include illuminance values calculated for different locations in the lighting design target area 314 and/or a heatmap that uses different colors and/or patterns to represent different illuminance values. To be clear, because the map 310 is dimensionally scaled to the geographic area shown in the map 310, physical distances in the geographic area can be determined based on corresponding locations and distances on the map 310 for the purpose of calculating illuminance values. For example, the distance between the location of a light fixture represented by the light fixture model 702 (shown in FIG. 9) and another location on the ground in the geographic area can be determined based on the location of the light fixture model 702 on the map 310 and the corresponding ground location on the map 310 as displayed on the screen 302.

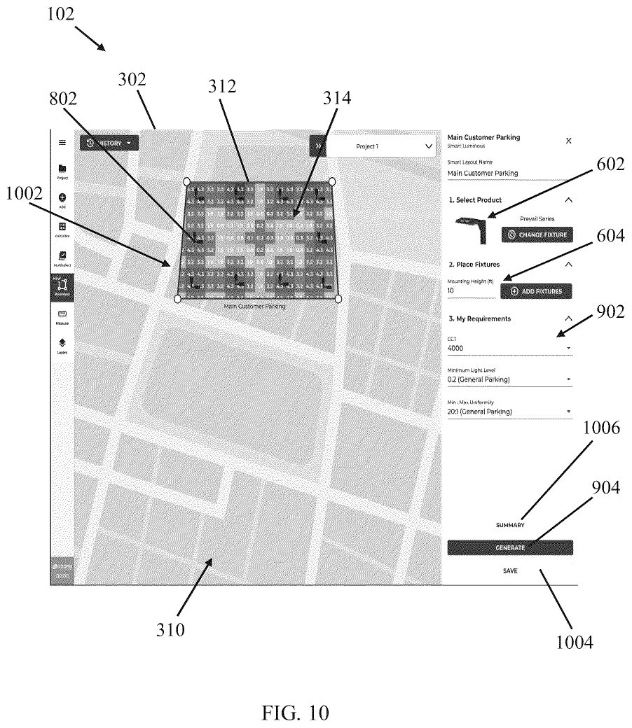

FIG. 10 illustrates illuminance information overlaid on the map 310 in the lighting design target area 314 according to an example embodiment. Referring to FIGS. 2A, 2B, and 10, in some example embodiments, at step 218, the method 200 of FIGS. 2A and 2B may include displaying, by the user device 102, illuminance information 1002 overlaid on the map 310 in the lighting design target area 314. As described above with respect to step 216, the illuminance information 1002 may include illuminance values calculated for different locations in the lighting design target area 314 and/or a heatmap that uses different colors and/or patterns to represent different illuminance values. Each illuminance value of the displayed illuminance information 1002 may be applicable to a section (e.g., 1 meter by 1 meter area, 5 meters by 5 meters area, or 10 meters by 10 meters area) of the lighting design target area 314. Each colored and/or patterned shape of the displayed illuminance information 1002 may be applicable to a section of the of the lighting design target area 314.

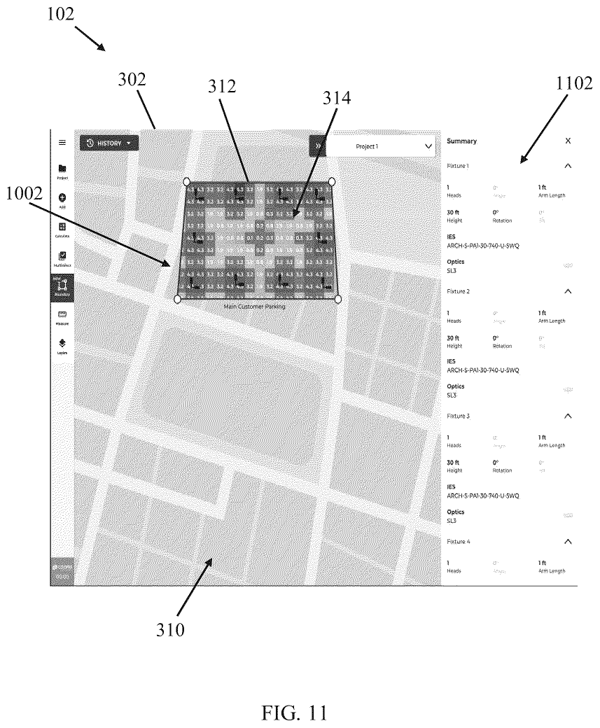

Referring to FIGS. 1-10, in some example embodiments, at step 220, the method 200 may include generating, by the user device 102, a lighting design summary including configuration information with respect to each one of the light fixtures represented by the light fixture models (e.g., the light fixture model 702, the light fixture model 802, etc.) displayed on the screen 302 in the lighting design target area 314. For example, the user may provide an input to the user device 102 via a summary icon 1006 displayed on the screen 302 to generate the lighting design summary. To illustrate, FIG. 11 illustrates a lighting design summary 1102 displayed on the screen of the user device 102 according to an example embodiment. Referring to FIGS. 1-11, in response to the user clicking or touching the summary icon 1006 shown in FIG. 10, the user device 102 may generate the lighting design summary 1102 may include configuration information related to each light fixture represented by the light fixture models overlaid on the map 310 in the lighting design target area 314.

Referring to FIGS. 1-11, in some example embodiments, before or after generating the lighting design summary 1102 shown in FIG. 11, the user may decide to change some aspects of the lighting design displayed on the screen 302. For example, based on the illuminance information 1002 displayed overlaid on the map 310 in the lighting design target area 314, the user may decide to change a light fixture represented by a light fixture model displayed on the map 310. In such cases, the user may click or touch the user input entry feature 602 shown in FIG. 10 to display on the screen 302 the light fixture menu 502 shown in FIG. 5, and the user may select a different light fixture from the light fixture menu 502. In response to the selection of a different light fixture, the user device 102 may display another light fixture model representing a newly selected light fixture to be displayed on the map 310 in the manner described above with respect to FIGS. 6-8. The user can also provide a different mounting height using the text entry form field 604 shown in FIG. 10.

For example, at step 222, the method 200 of FIGS. 2A and 2B may include displaying, in response to a new location user input received by the user device 102, the light fixture model at a new location within the lighting design target area 314. For example, the light fixture model 802 may be moved to a different location in the lighting design target area 314, for example, by dragging and dropping the light fixture model 802 at the new location or by clicking or touching at the new location after selecting the light fixture model 802. The user can also provide inputs to the user device 102 to display one or more light fixture models in the lighting design target area 314 at user indicated location(s), to delete a light fixture model from the lighting design target area 314, and/or to change the configuration (i.e., provide new configuration user inputs) of one or more light fixtures represented by the light fixture models in the lighting design target area 314 as described above, for example, with respect to FIGS. 7 and 8. After the changes/updates are made, the user may use the generate icon 904 to provide an input to the user device 102 to generate new illuminance information that depends on the change/updates. At step 224, the method 200 of FIGS. 2A and 2B may include displaying the new illuminance information overlaid on the lighting design target area 314 bound by the boundary line 312 shown, for example, in FIG. 10.

In some example embodiments, the user may provide an input to the user device 102 by clicking or touching a save icon 1004 displayed on the screen 302 as shown in FIG. 10 to store the lighting design information. The stored lighting design information may include information such as the locations of the light fixtures corresponding to the light fixture models displayed in the lighting design target area 314 shown on the screen 302, light fixture names, light fixture configurations (e.g., number of heads, tilt angle, rotational angle, etc.), mounting height, associated/selected photometric data file, optics, etc. that can be used to subsequently display the lighting layout displayed on the screen 302 shown in FIG. 10. The user device 102 may store the lighting design information in response to a user input provided via the save icon 1004 that may be received before or after the changes/updates described with respect to step 222 are made. The user device 102 may store the lighting design information at the user device 102 or at another local or remote location as can be readily understood by those of ordinary skill in the art with the benefit of this disclosure.

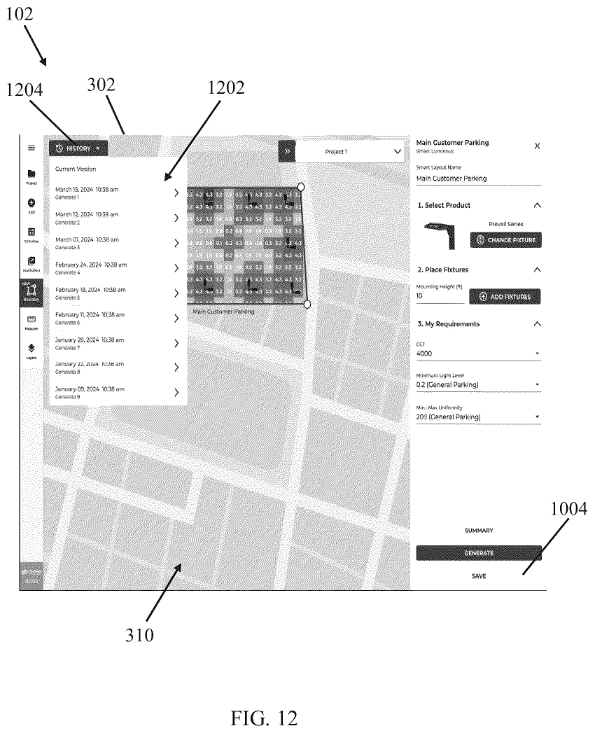

In general, the stored lighting design information can be subsequently accessed to display the map 310, the boundary line 312, the light fixture models (e.g., the light fixture models 702, 802), and the illuminance information 1002 overlaid on the map 310 in the lighting design target area 314. For example, FIG. 12 shows a lighting design list 1202 that is displayed on the screen 302 of the user device 102 according to an example embodiment. The lighting design list 1202 may be a list of lighting designs that each correspond to respective lighting design information previously stored in response to user inputs provided using the save icon 1004. The lighting design list 1202 may be displayed on the screen 302 in response to a user clicking or touching a history icon 1204 displayed on the screen 302. For example, after the lighting design list 1202 is displayed on the screen 302, a user may select one of the lighting designs from the lighting design list 1202, and the user device 102 may display the lighting layout on the screen 302 in response to the user input.

Referring to FIGS. 1-12, by using the user device 102 as described above, a person with limited lighting knowledge can design the lighting for a particular area. By using a map of an area such as the map 310 that can show roads, walkways, parking lots, buildings, and other structures, the user device 102 can avoid the need to travel and examine an area for lighting design. By providing user input entry features to a user, the user device 102 guides a person with limited lighting design knowledge to provide information relevant to lighting design. In some example embodiments, by not requiring a user to select, identity, or otherwise provide a photometric data file with respect to light fixtures and respective light fixture models, the user device 102 can significantly reduce the burden on the user in performing a lighting design. By allowing a user to update or otherwise change user inputs provided to the user device 102, the user device 102 enables the user to improve lighting design performed using the user device 102. By displaying illuminance information for a lighting design target area, such the lighting design target area 314, identified by a user, the user device 102 provides a visual representation of the lighting design that is easy for the user to interpret and understand. By allowing the user to indicate a lighting design target area using (e.g., drawing) a boundary line (e.g., the boundary line 312) that encloses the particular lighting design target area, the user device 102, lighting design can be performed for a more precise area.

In some alternative embodiments, the boundary area 314 may have a different shape than shown without departing from the scope of this disclosure.

In some alternative embodiments, the method 200 may include more or fewer steps than shown in FIGS. 2A and 2B without departing from the scope of this disclosure. In some alternative embodiments, the steps of the method 200 may be performed in a different order than shown without departing from the scope of this disclosure. In some alternative embodiments, the user device 102 may display different user input entry features than shown without departing from the scope of this disclosure. For example, some of the icons for user input entry may instead be text entry features. In some alternative embodiments, some of the user input entry features may be at different locations on the screen 302 than shown without departing from the scope of this disclosure. In some alternative embodiments, some of the user input entry features displayed on the screen 302 may be combined into a different type of user input entry feature. For example, some icons can be replaced with a dropdown menu. In some alternative embodiments, the user device 102 may provide more or fewer user input entry features than shown in FIGS. 3-12 without departing from the scope of this disclosure.

Although particular embodiments have been described herein in detail, the descriptions are by way of example. The features of the embodiments described herein are representative and, in alternative embodiments, certain features, elements, and/or steps may be added or omitted. Additionally, modifications to aspects of the embodiments described herein may be made by those skilled in the art without departing from the scope of the following claims, the scope of which are to be accorded the broadest interpretation so as to encompass modifications and equivalent structures.

1. A lighting design method, comprising:
receiving, by a user device, a map of a geographic area;
displaying, by the user device, the map of the geographic area on a screen;
displaying, by the user device, a boundary line overlaid on the map in response to a boundary line user input provided to the user device, a lighting design target area being bound by the boundary line;
displaying, by the user device, a light fixture model overlaid on the map within the lighting design target area, the light fixture model being overlaid at a location indicated by a location indicator user input, and the light fixture model representing a light fixture selected from a light fixture menu displayed on the screen;
generating illuminance information automatically at least based on user provided information including a configuration of the light fixture; and
displaying, by the user device, the illuminance information overlaid on the lighting design target area.

2. The method of claim 1, further comprising displaying, by the user device, a second light fixture model overlaid on the map within the lighting design target area, wherein the second light fixture model is displayed at a second location indicated by a second location indicator user input, wherein the second light fixture model represents a second light fixture selected from the light fixture menu, and wherein the illuminance information is generated further based on a configuration of the second light fixture indicated by a second configuration user input.

3. The method of claim 2, wherein the illuminance information is generated further based on desired lighting characteristics of the light design target area indicated by a lighting characteristics user input and wherein the desired lighting characteristics include correlated color temperature information and lighting uniformity information.

4. The method of claim 3, wherein the illuminance information is generated further based on photometric data of a photometric data file selected by the user device.

5. The method of claim 4, wherein the configuration user input includes a number of heads of the light fixture, wherein the configuration of the second light fixture includes a number of heads of the second light fixture, and wherein the illuminance information is generated further based on a light fixture mounting height indicated by a mounting height user input.

6. The method of claim 2, further comprising displaying, by the user device, new illuminance information overlaid on the lighting design target area, wherein the new illuminance information is generated at least based on a new configuration of the light fixture and wherein the new configuration of the light fixture is indicated by a new configuration user input.

7. The method of claim 1, further comprising receiving, by the user device, geographic location user input indicating a geographic location, wherein the geographic area includes the geographic location, and wherein the map of the geographic area is displayed in response to the geographic location user input.

8. The method of claim 1, further comprising displaying, by the user device, the light fixture menu in response to a light fixture menu user input.

9. The method of claim 1, further comprising deleting the second light fixture model in response to a light fixture removal user input received by the user device.

10. The method of claim 1, further comprising displaying, in response to a new location user input received by the user device, the light fixture model at a new location within the lighting design target area.

11. The method of claim 1, further comprising generating a lighting design summary including light fixture mounting height information and configuration information indicating the configuration of the light fixture and the configuration of the second light fixture.

12. The method of claim 1, further comprising storing lighting design information that is subsequently accessible to display the map on the screen, the boundary line overlaid on the map, the light fixture model overlaid on the map within the lighting design target area, the second light fixture model overlaid on the map within the lighting design target area, and the illuminance information overlaid on the map in the lighting design target area.

13. The method of claim 1, wherein the map is shown in a webpage displayed on the screen.

14. The method of claim 1, the user device is a portable device.

15. The method of claim 1, wherein the map of the geographic area is obtained from a mapping service server.
